(19) United States
(12) Patent Application Publication
(10) Pub. No.: US 2024/0111281 A1
(43) Pub. Date: Apr. 4, 2024

(54) Deterioration Prediction System and Deterioration Prediction Method for Semiconductor Manufacturing Equipment or Semiconductor Inspection Equipment

(71) Applicant: Hitachi High-Tech Corporation, Tokyo (JP)

(72) Inventors: Kenji TAMAKI, Tokyo (JP); Wataru KANNO, Tokyo (JP); Takashi DOI, Tokyo (JP); Fumihiro SASAJIMA, Tokyo (JP)

(21) Appl. No.: 18/375,734

(22) Filed: Oct. 2, 2023

(30) Foreign Application Priority Data
Oct. 4, 2022 (JP) 2022-160342

(51) Int. Cl. G05B 23/02; G05B 13/04

(52) U.S. Cl. CPC G05B 23/0283; G05B 13/048; G05B 23/024

(57) ABSTRACT

A deterioration prediction system for a semiconductor manufacturing equipment or a semiconductor inspection equipment, including: an input device receiving, as an input, time series data indicating a state of the equipment; a deterioration prediction device having an estimation unit discriminating fluctuation in the time series data into fluctuation caused by changing setting of the equipment and fluctuation caused by deterioration of the equipment and estimating a time point when the setting is changed, a division unit dividing the time series data into the plurality of periods bounded by the time points, a discrimination unit discriminating at least a trend component from the fluctuation in the time series data in the period, and a prediction unit predicting the deterioration of the equipment based on at least the trend component; and an output device outputting a result of the prediction.

### BACKGROUND OF THE INVENTION

### 1. Field of the Invention

The present invention relates to a deterioration prediction system and a deterioration prediction method for semiconductor manufacturing equipment or semiconductor inspection equipment.

### 2. Description of Related Art

A method has been proposed in which a value of a monitoring item of equipment is measured by a sensor and deterioration of the equipment is estimated from time series data of the measured value (for example, Patent Literature 1 (JP2021-135513A)). For example, when a roller for feeding paper is provided in a printer, if the roller wears, the paper becomes slippery during paper feeding, and thus, vibration of the roller increases. For this reason, when the monitoring item is the vibration of the roller, the time series data of the vibration has an increasing tendency. In the method described in Patent Literature 1 (JP2021-135513A), when the time series data has only one of the increasing tendency and the decreasing tendency, the trend component illustrating the increasing tendency or the decreasing tendency is extracted from the time series data, and the deterioration of the equipment is estimated based on the trend component.

### SUMMARY OF THE INVENTION

However, the method described in Patent Literature 1 (JP2021-135513A) does not assume that the tendencies of the trend component change from the increase to the decrease or from the decrease to the increase at a certain time point, and in this case, it is difficult to estimate the deterioration of the equipment.

The present invention has been made in view of such circumstances, and an object of the present invention is to make it possible to estimate the deterioration of the equipment even when the tendencies in the trend component included in monitoring items of the equipment change.

The present application includes a plurality of means for solving at least a portion of the above problems, and examples thereof are as follows.

In order to solve the above problems, a deterioration prediction system for a semiconductor manufacturing equipment or a semiconductor inspection equipment includes: an input device receiving, as an input, time series data indicating a state of the equipment; a deterioration prediction device having an estimation unit discriminating fluctuation in the time series data into fluctuation caused by changing setting of the equipment and fluctuation caused by deterioration of the equipment and estimating a time point when the setting is changed, a division unit dividing the time series data into the plurality of periods bounded by the time points, a discrimination unit discriminating at least a trend component from the fluctuation in the time series data in the period, and a prediction unit predicting the deterioration of the equipment based on at least the trend component; and an output device outputting a result of the prediction.

According to the present invention, the deterioration of the equipment can be estimated even when the tendencies of the trend component included in the monitoring item of the equipment change.

Problems, configurations, and effects other than those described above will be clarified by the following description of the embodiments.

### BRIEF DESCRIPTION OF THE DRAWINGS

FIG. 1 is a configuration diagram illustrating an example of a deterioration prediction system according to a first embodiment;

FIG. 2 is a configuration diagram illustrating an example of scanning electron microscope equipment in which the deterioration prediction system according to the first embodiment predicts deterioration;

FIG. 3 is a diagram illustrating an example of a hardware configuration of the deterioration prediction device according to the first embodiment;

FIG. 4 is a diagram illustrating an example of a flowchart of a deterioration prediction method according to the first embodiment;

FIG. 5 is a diagram illustrating examples of a graph of time series data of a monitoring item A and a graph of time series data of a monitoring item B according to the first embodiment;

FIG. 6 is a schematic diagram illustrating an example of a trend component table according to the first embodiment;

FIG. 7 is a diagram illustrating examples of a graph of time series data of a monitoring item A and a graph of time series data of a monitoring item B obtained by extending a trend component according to the first embodiment;

FIG. 8 is a schematic diagram illustrating a screen display example of a display device according to the first embodiment;

FIG. 9 is a diagram illustrating an example of a flowchart in the first embodiment of an estimation process for estimating a time point when setting of the equipment is changed; and

FIG. 10 is a diagram illustrating an example of a flowchart in a second embodiment of the estimation process for estimating a time point when setting of the equipment is changed.

### DESCRIPTION OF EMBODIMENTS

Hereinafter, embodiments according to the present invention will be described with reference to the drawings. It is noted that, in all the drawings for describing the embodiments, in principle, the same members are denoted by the same reference numerals, and repeated description thereof will be omitted as appropriate. In addition, in the following embodiments, it goes without saying that the constituent elements (including element steps and the like) are not necessarily essential unless otherwise specified or clearly considered essential in principle. In addition, when saying “configured with A”, “formed with A”, “having A”, or “including A”, it goes without saying that, unless specifically stated that it is only that element, other elements are not excluded. Similarly, in the following embodiments, when referring to the shape, positional relationship, or the like of constituent components and the like, unless otherwise explicitly stated or in principle clearly considered, it is assumed that the shapes or the like include substantially approximate or similar shapes or the like.

### First Embodiment

In equipment having a mechanical mechanism such as a printer, the mechanism wears and deteriorates due to sliding. When vibration of the mechanism is measured by using an acceleration sensor or the like, and when time series data is acquired and monitored, the vibration increases due to the deterioration. Although a rate of increase in vibration can change, it does not turn to decrease due to the deterioration, and at least the decrease in vibration does not indicate the progress of the deterioration. Therefore, when the trend component is extracted from the time series data of the vibration to diagnose a degree of increase, current deterioration can be estimated, or future deterioration can be predicted.

On the other hand, in this embodiment, a semiconductor manufacturing equipment is the target for detection of the deterioration occurred up to the current time point and for prediction of the deterioration in the future. Even in the semiconductor manufacturing equipment that manufactures semiconductor devices by using physical or chemical reactions in a chamber, the monitoring items for monitoring the state of the equipment fluctuate due to the deterioration of parts constituting the equipment.

However, in the case of semiconductor manufacturing equipment, since a fluctuation trend of the time series data of the monitoring items due to the deterioration has both the increasing tendency and the decreasing tendency, there is a characteristic that the fluctuation trend of the time series data of the monitoring items turns to increase or decrease after a certain point according to the setting condition of the equipment. Accordingly, there is a problem that it is difficult to predict the deterioration of the equipment by extracting the trend component of the monitoring item with high accuracy. For example, a semiconductor ion implanting equipment using a charged particle beam corresponds to such equipment for which it is difficult to predict the deterioration. Such characteristics are that, in the semiconductor inspection equipment such as electron microscopes for inspecting semiconductor devices, in this embodiment, not only the semiconductor manufacturing equipment but also the semiconductor inspection equipment is targeted for the deterioration prediction. In addition to the semiconductor manufacturing equipment and the semiconductor inspection equipment, this embodiment can be applied to predict the deterioration of various equipment in which the tendencies of the trend component change.

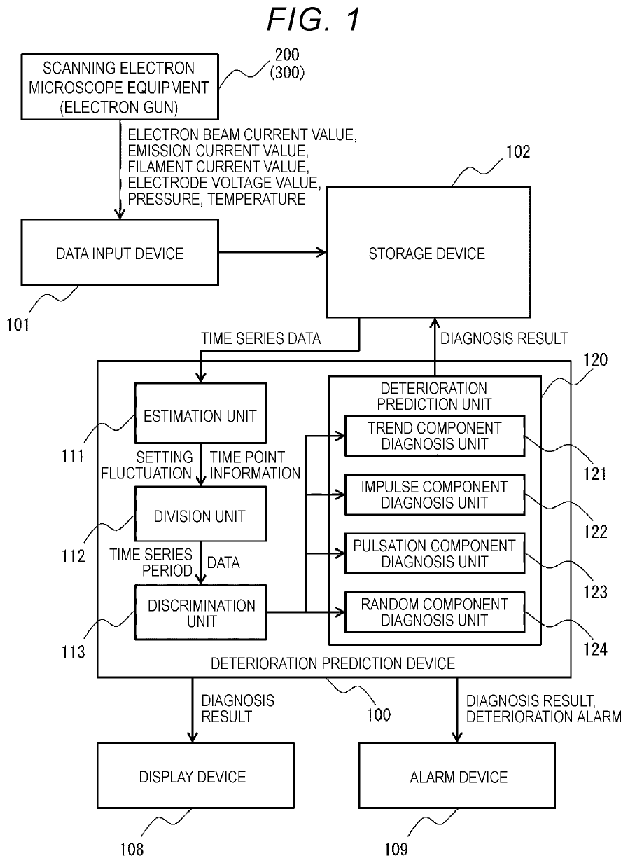

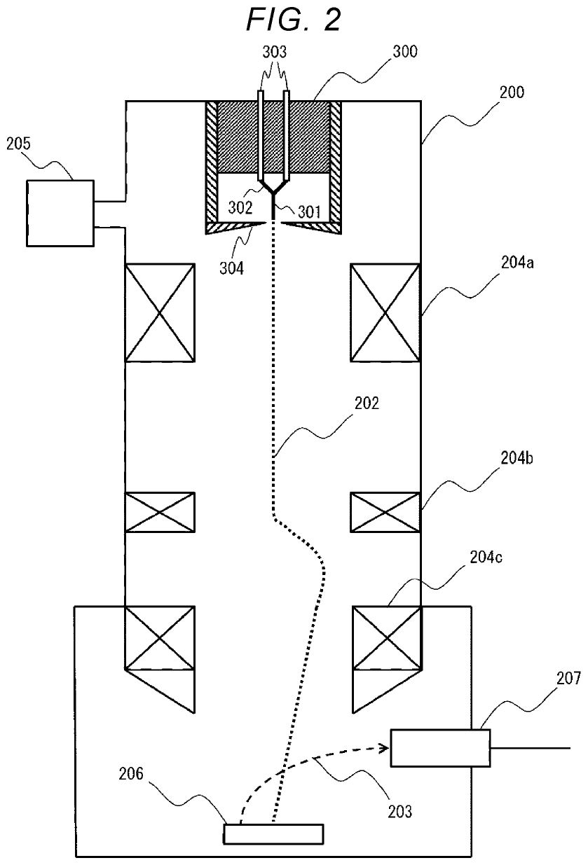

FIG. 1 is a configuration diagram illustrating an example of a deterioration prediction system according to this embodiment. In addition, FIG. 2 is a configuration diagram illustrating an example of scanning electron microscope equipment for predicting deterioration by the deterioration prediction system. The scanning electron microscope equipment is an example of charged particle beam equipment used to inspect semiconductor devices.

As illustrated in FIG. 2, scanning electron microscope equipment 200 scans and irradiates a semiconductor sample 206 with an electron beam 202 extracted from an electron gun 300 in the chamber maintained in the vacuum by a vacuum pump 205 by using coil lenses 204a, 204b, and 204c. The electron beam 202 is an example of the particle beam.

The intensity of signal electrons 203 emitted from the semiconductor sample 206 is detected by a detector 207, and a circuit pattern formed on a semiconductor sample 206 is inspected by generating the image from the intensity on the scanning plane. In order to obtain the image for highly accurate inspection, the current value of the electron beam 202 needs to be maintained constantly within a predetermined range.

In the electron gun 300, the electron source 301 emitting the electron beam 202 is connected to the filament 302, and the filament 302 is connected to the electrode 303. The electrode 304 surrounds the electron source 301, and the electron beam 202 is accelerated by the voltage applied between the electrode 303 and the electrode 304.

As illustrated in FIG. 1, a deterioration prediction system for predicting deterioration of the scanning electron microscope equipment 200 includes a deterioration prediction device 100, a data input device 101, a storage device 102, a display device 108, and an alarm device 109. It is noted that a portion of the processes and functions of the deterioration prediction system may be incorporated in quipment such as the scanning electron microscope equipment 200.

The data input device 101 is a device collecting values of the monitoring items from the scanning electron microscope equipment 200 at a predetermined timing or a predetermined cycle, and stores these values in the storage device 102 together with the collected time data. For example, the data input device 101 is an analog/digital (A/D) converter converting an analog value of the monitoring item into a digital value and stores the digital value associated with time data in the storage device 102. Hereinafter, the time data and the monitoring items associated with the time data are also referred to as the time series data indicating the state of the scanning electron microscope equipment 200.

The monitoring items include an “emission current”, an “electron beam current”, a “filament current”, an “electrode voltage”, a “pressure”, and a “temperature”.

The “emission current” is an item name of an entire current value emitted from the electron source 301 (FIG. 2). The “electron beam current” is an item name of the current value of the electron beam 202 and indicates a portion of the “emission current” that is irradiated to the semiconductor sample 206.

The “filament current” is an item name of the current value of the current supplied to the filament 302 and heats the electron source 301 to a predetermined temperature to prepare the condition for obtaining a predetermined value of the “electron beam current”.

The “electrode voltage” is an item name of the voltage value applied between the electrodes 303 and 304 and forms the electric field around the electron source 301 to prepare the condition for obtaining a predetermined value of the “electron beam current”.

The “pressure” is an item name of pressure inside the chamber of the scanning electron microscope equipment 200. The “temperature” is an item name of the temperature of the filament 302.

In this example, the time series data are stored in the storage device 102 for each of the “emission current”, the “electron beam current”, the “filament current”, the “electrode voltage”, the “pressure”, and the “temperature”.

The storage device 102 is a storage device such as a hard disk drive (HDD) or a solid state drive (SSD).

The deterioration prediction device 100 is a computer such as a server or a personal computer (PC) that diagnoses the deterioration of the electron gun 300 based on the time series data stored in the storage device 102.

The storage device 102 may be a storage device included in the deterioration prediction device 100 or may be a storage device included in the computer different from the deterioration prediction device 100. Furthermore, the storage device 102 may be a storage device on a cloud, connected to the deterioration prediction device 100 via the Internet.

The deterioration prediction device 100 includes an estimation unit 111, a division unit 112, a discrimination unit 113, and a deterioration prediction unit 120.

The estimation unit 111 is a functional unit that discriminates the fluctuations in the time series data into the fluctuation caused by changing the setting of the scanning electron microscope equipment 200 and the fluctuation caused by the deterioration of the scanning electron microscope equipment 200 and estimates the time point when the setting of the scanning electron microscope equipment 200 is changed. The estimation method will be described later.

The division unit 112 is a functional unit dividing time series data into a plurality of periods with the time point estimated by the estimation unit 111 set as a boundary.

The discrimination unit 113 is a functional unit discriminating a trend component, an impulse component, a pulsation component, and a random component from the fluctuations in the time series data in the period divided by the division unit 112. For example, the discrimination unit 113 extracts the moving median series or moving average series of the time series data as the trend component. The trend component is a component indicating the approximate increase or decrease tendency of the time series data in a certain period.

The discrimination unit 113 also extracts the impulse component from the difference between the trend component and the original time series data. The impulse component is a signal appearing abruptly in the original time series data.

Furthermore, the discrimination unit 113 obtains residual data by subtracting the trend component and the impulse component from the original time series data. When an autocorrelation function value of the residual data is larger than a predetermined threshold value, the discrimination unit 113 extracts the residual data as the pulsation component. The pulsation component is a component indicating periodicity in the original time series data.

Further, when the autocorrelation function value is the threshold value or less, the discrimination unit 113 extracts the residual data as the random component. The random component is a component that appears randomly in the time series data.

The deterioration prediction unit 120 is a functional unit which predicts the deterioration of the scanning electron microscope equipment 200 based on at least the trend component and outputs diagnosis results based on the prediction to the storage device 102, the display device 108, and the alarm device 109.

As an example, the deterioration prediction unit 120 includes a trend component diagnosis unit 121, an impulse component diagnosis unit 122, a pulsation component diagnosis unit 123, and a random component diagnosis unit 124. The trend component diagnosis unit 121 is a functional unit calculating a deterioration index indicating how much the scanning electron microscope equipment 200 deteriorates based on the trend component. The impulse component diagnosis unit 122 is a functional unit calculating the deterioration index based on the impulse component. In addition, the pulsation component diagnosis unit 123 is a functional unit calculating the deterioration index based on the pulsation component. The random component diagnosis unit 124 is a functional unit calculating the deterioration index based on the random component.

The display device 108 is an example of the output device, and the display device 108, which is a display device such as a liquid crystal display or an organic electro luminescence (EL) display displaying a diagnosis result of the deterioration prediction unit 120, may be the display device included in the computer different from the deterioration prediction device 100.

The alarm device 109 is a functional unit transmitting an alarm mail to the person in charge registered in advance when the diagnosis result requires urgency. The alarm device 109 may be a computer different from the deterioration prediction device 100.

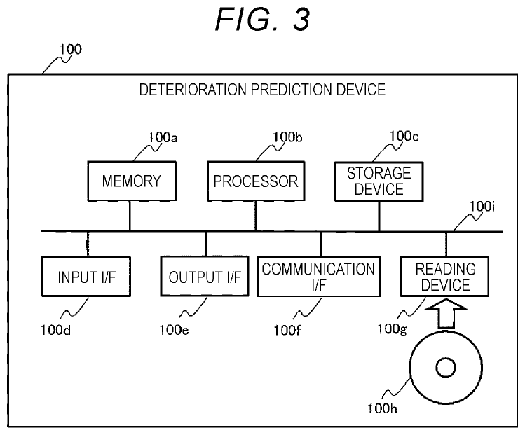

FIG. 3 is a diagram illustrating an example of a hardware configuration of the deterioration prediction device 100. As illustrated in FIG. 3, the deterioration prediction device 100 includes a memory 100a, a processor 100b, a storage device 100c, an input interface (I/F) 100d, an output I/F 100e, a communication I/F 100f, and a reading device 100g. These devices are interconnected by a bus 100i.

The memory 100a is hardware temporarily storing data such as a dynamic random access memory (DRAM), on which a deterioration prediction program according to this embodiment is loaded.

The processor 100b is a processor device such as a central processing unit (CPU) or a graphical processing unit (GPU) that controls each unit of the deterioration prediction device 100.

Units 111 to 113 and units 120 to 124 in FIG. 1 are implemented by the processor 100b executing the deterioration prediction program in cooperation with the memory 100a.

The storage device 100c is a nonvolatile storage device such as a hard disk drive (HDD) or a solid state drive (SSD) and stores the deterioration prediction program according to this embodiment. Instead of storing the deterioration prediction program in the storage device 100c, the deterioration prediction program may be stored in the storage device 102 (refer to FIG. 1). Alternatively, the storage device 102 (refer to FIG. 1) may be omitted, and various data may be stored in the storage device 100c.

The deterioration prediction program may be recorded in a computer-readable recording medium 100h, and the processor 100b may read the deterioration prediction program from the recording medium 100h.

Examples of the recording medium 100h include physical portable recording media such as a compact disc-read only memory (CD-ROM), a digital versatile disc (DVD), and a universal serial bus (USB) memory. A semiconductor memory such as a flash memory and a hard disk drive may be used as the recording media 100h.

The deterioration prediction program may be stored in a device connected to a public line, the internet, a local area network (LAN), or the like. In this case, the processor 100b may read and execute the deterioration prediction program.

The input I/F 100d is an interface with an input device (not illustrated) such as a keyboard or a mouse for the user to input various data to the deterioration prediction device 100. The output I/F 100e is an interface with the display device 108 and the alarm device 109 in FIG. 1. The communication I/F 100f is an interface with networks such as the internet and a local area network (LAN).

The reading device 100g is hardware such as a CD drive for reading data recorded on the recording medium 100h.

Next, the deterioration prediction method according to this embodiment will be described.

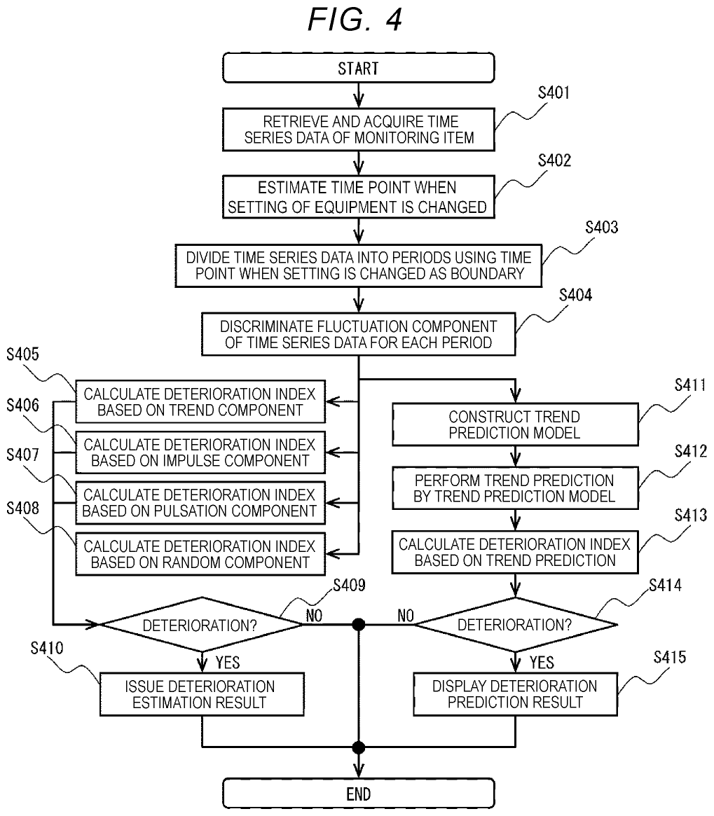

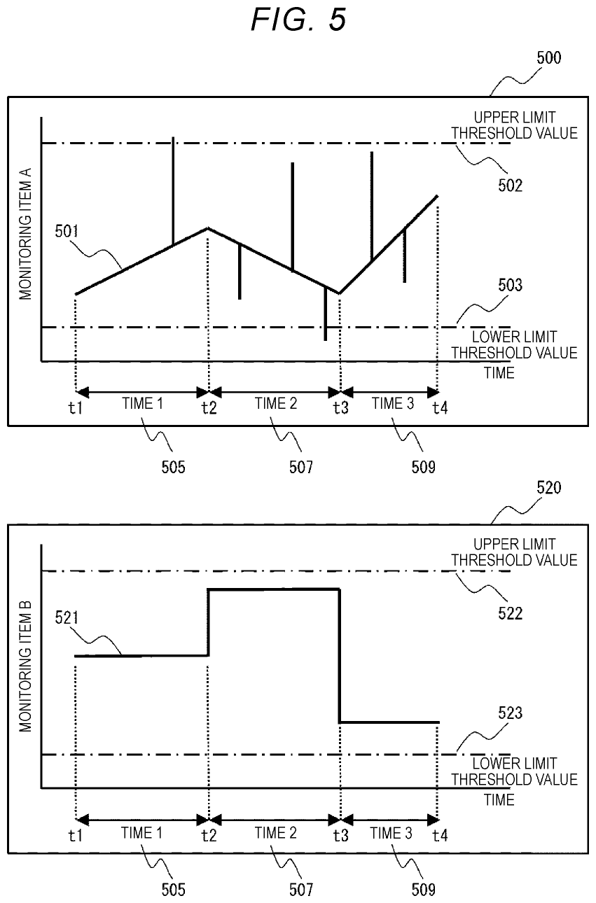

FIG. 4 is a diagram illustrating an example of a flowchart of the deterioration prediction method according to this embodiment. Hereinafter, the deterioration prediction method will be described with reference to FIG. 5 as well.

FIG. 5 is a diagram illustrating examples of a graph 500 of time series data 501 of the monitoring item A and a graph 520 of time series data 521 of the monitoring item B, respectively. Which of the “emission current,” the “electron beam current,” the “filament current,” and the “electrode voltage” each of the monitoring item A and the monitoring item B indicates will be clarified later.

In addition, in the time series data 501 of the monitoring item A, an upper limit threshold value 502 and a lower limit threshold value 503 are set in advance. The upper limit threshold value 502 and the lower limit threshold value 503 are the upper and lower limits of a normal range in which the scanning electron microscope equipment 200 is expected not to deteriorate. When the time series data 501 exceeds the normal range, the scanning electron microscope equipment 200 deteriorates, and thus, the maintenance work is likely to be required.

Similarly, the upper limit threshold value 522 and the lower limit threshold value 523 are set in advance for the time series data 521 of the monitoring item B. When the time series data 521 exceeds the normal range defined by the upper limit threshold value 522 and the lower limit threshold value 523, the possibility that the scanning electron microscope equipment 200 deteriorates is increased.

First, in step S401 of FIG. 4, the estimation unit 111 retrieves and acquires data in the designated period among the time series data of the monitoring items stored in the storage device 102. The designated period is, for example, the period from a time point t1 to a time point t4 in FIG. 5. The start time point (t1) and the end time point (t4) of the designated period are input from an input device (not illustrated) such as a keyboard, and the estimation unit 111 receives the input. In addition, the monitoring item of which target is acquisition of the time series data may be designated by the user, for example, operating the input device (not illustrated).

Next, the estimation unit 111 performs the estimation process for estimating the time point when the setting is changed with the fluctuations appearing in the acquired time series data discriminated into the fluctuations caused by changing the setting of the scanning electron microscope equipment 200 and the fluctuations caused by the deterioration of the equipment (step S402). In the example of FIG. 5, the time point t2 and the time point t3 are estimated as the time points where the settings are changed. The details of this estimation process will be described later.

Next, the division unit 112 divides the time series data into the plurality of periods with the time points when the setting is estimated to be changed as a boundary (step S403). In the example of FIG. 5, the division unit 112 divides the time series data into the first period 505, the second period 507, and the third period 509.

Next, the discrimination unit 113 discriminates the trend component, the impulse component, the pulsation component, and the random component from the time series data divided in each period (step S404). Furthermore, the discrimination unit 113 approximates the discriminated trend component with the polygonal line regression model and stores the result in the storage device 102 as a trend component table.

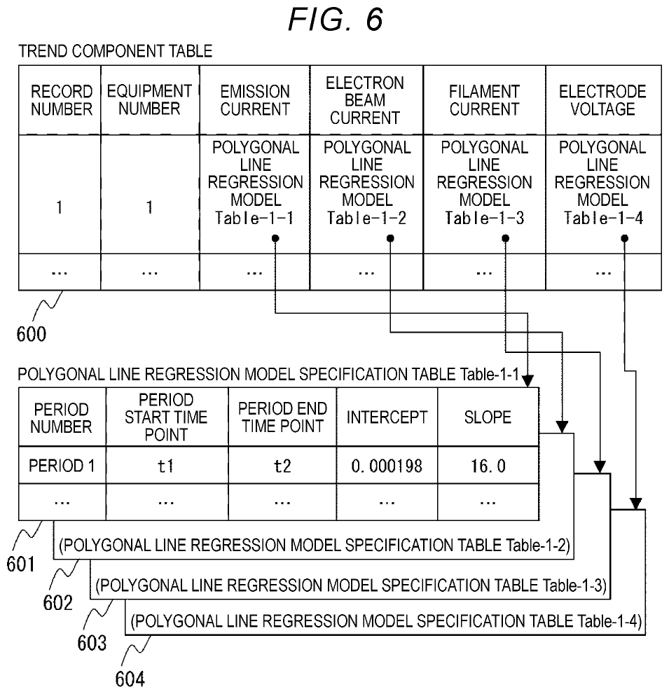

FIG. 6 is a schematic diagram illustrating an example of the trend component table. As illustrated in FIG. 6, a trend component table 600 is a table in which a “record number”, “equipment number”, an “emission current”, an “electron beam current”, a “filament current”, and an “electrode voltage” are associated with each other.

The “record number” is the number that uniquely identifies each row of the trend component table. The “equipment number” is the number that uniquely identifies the plurality of semiconductor manufacturing equipment and semiconductor inspection equipment installed in the manufacturing process of the semiconductor devices.

The “emission current”, the “electron beam current”, the “filament current”, and the “electrode voltage” are monitoring items of the equipment that is a target of the monitoring as described above. Link to polygonal line regression model usage tables 601 to 604 corresponding to the monitoring items are stored in these monitoring items.

For example, a link to the polygonal line regression model usage table 601 is stored in the monitoring item of the “emission current” with the “record number” of “1”. The link is the path indicating the storage location of the polygonal line regression model usage table 601 in the storage device 102.

The polygonal line regression model usage table 601 is a table in which a “period number”, a “period start time point”, a “period end time point”, an “intercept”, and a “slope” are associated with each other.

The “period number” is the number that uniquely identifies each of the plurality of periods divided in step S403. The “period start time point” and the “period end time point” are the start time point and the end time point of the period, and are the time points when the setting is estimated to be changed in step S402.

The “intercept” is a y-coordinate of the straight line indicated by the regression equation that approximates the trend component intersecting a y-axis. It is noted that the y-axis is a coordinate axis that passes through the “period start time point” in the period and is perpendicular to an x-axis representing time. In addition, the “slope” is a slope of the straight line.

By generating the trend component table 600, the trend component for each period can be accurately stored and reproduced, which can be used to predict future equipment deterioration and by connecting the straight lines in a plurality of the periods, the polygonal line regression model approximating the time series data with the polygonal line can be obtained.

The process refers to FIG. 4 again. After that, the process is divided into the determination of whether the scanning electron microscope equipment 200 has deteriorated within the designated period and the determination of whether the scanning electron microscope equipment 200 will deteriorate in the future.

The former determination of whether the scanning electron microscope equipment 200 has deteriorated within the designated period will be described first below.

First, the trend component diagnosis unit 121 calculates a deterioration index indicating whether the scanning electron microscope equipment 200 has deteriorated based on the trend component (step S405). As the deterioration index, for example, there is a numerical value indicating whether the trend component has exceeded the normal range defined by the upper limit threshold value 502 and the lower limit threshold value 503. Alternatively, the number of times the trend component exceeds the normal range in the designated period may be used as the deterioration index. Furthermore, a sum of the number of times the trend component is changed from increase to decrease and the number of times the trend component is changed from decrease to increase may be used as the deterioration index. The number of times the trend component has changed in this manner can be calculated by the trend component diagnosis unit 121 based on the polygonal line regression model described with reference to FIG. 6.

Further, a value obtained by multiplying each of various deterioration indexes described above by the weighting factor and summing these indexes may be used as one deterioration index.

Next, as the deterioration index which the impulse component diagnosis unit 122 calculates based on the impulse component (step S406), for example, there is a numerical value indicating whether the impulse component has exceeded the normal range defined by the upper limit threshold value 502 and the lower limit threshold value 503. Alternatively, the number of times the impulse component exceeds the normal range in the designated period may be used as a deterioration index. Furthermore, the maximum crest value of the impulse components or the occurrence of impulses in the designated period may be used as a deterioration index.

Further, a value obtained by multiplying each of various deterioration indexes described above by the weighting factor and summing these indexes may be used as one deterioration index.

Next, the pulsation component diagnosis unit 123 calculates the deterioration index based on the pulsation component (step S407). As the deterioration index, for example, there is a numerical value indicating whether the pulsation component has exceeded the normal range defined by the upper limit threshold value 502 and the lower limit threshold value 503. Alternatively, the number of times the pulsation component exceeds the normal range in the designated period may be used as a deterioration index. Furthermore, the maximum crest value of the pulsation component in the designated period may be used as a deterioration index. In addition, the maximum value of the autocorrelation function of the pulsation component or the period between the maximum values may be used as a deterioration index.

It is noted that the value obtained by multiplying each of the various deterioration indexes described above by the weighting factor and adding the multiplied deterioration indexes may be used as one deterioration index.

Next, the random component diagnosis unit 124 calculates the deterioration index based on the random component (step S408). As a deterioration index, for example, there is a numerical value indicating whether the random component has exceeded the normal range defined by the upper limit threshold value 502 and the lower limit threshold value 503. Alternatively, the number of times the random component exceeds the normal range in the designated period may be used as the deterioration index. Furthermore, a maximum value or a root mean square (RMS) value of the random component in the designated period may be used as the deterioration index.

It is noted that the value obtained by multiplying each of the various deterioration indexes described above by the weighting factor and adding the multiplied deterioration indexes may be used as one deterioration index.

Next, the deterioration prediction unit 120 determines whether the scanning electron microscope equipment 200 has deteriorated within the designated period based on the deterioration index calculated from at least the trend component among the trend component, the impulse component, the pulsation component, and the random component (step S409). For example, when the deterioration index has exceeded the threshold value, the deterioration prediction unit 120 determines that the scanning electron microscope equipment 200 has deteriorated within the designated period and when the deterioration index has not exceeded the threshold value, the deterioration prediction unit 120 determines that the scanning electron microscope equipment 200 has not deteriorated within the designated period.

Further, deterioration prediction unit 120 may calculate the value obtained by multiplying each deterioration index calculated from at least the trend component by the weighting factor and adding the multiplied deterioration indexes among the trend component, the impulse component, the pulsation component, and the random component. Then, when the value has exceeded the threshold value, the deterioration prediction unit 120 may determine that the scanning electron microscope equipment 200 has deteriorated within the designated period and when the value has not exceeded the threshold value, the deterioration prediction unit 120 may determine that the scanning electron microscope equipment 200 has not deteriorated within the designated period.

Then, deterioration prediction unit 120 stores the deterioration index calculated from each of the trend component, the impulse component, the pulsation component, and the random component in the storage device 102. Further, the deterioration prediction unit 120 stores the deterioration determination result based on the deterioration index in the storage device 102 as the diagnosis result of the scanning electron microscope equipment 200.

Herein, when it is determined that the scanning electron microscope equipment 200 has not deteriorated within the designated period (NO in step S409), the former determination process ends.

On the other hand, when it is determined that the scanning electron microscope equipment 200 has deteriorated within the designated period (YES in step S409), the former determination process proceeds to step S410. In step S410, the deterioration prediction unit 120 instructs the alarm device 109 to issue the alarm, and the alarm device 109 receiving the instruction issues the alarm. As the example, the alarm device 109 transmits the alarm mail to the person in charge registered in advance. In addition, the alarm device 109 may attach the diagnosis result to the alarm mail.

The latter determination of whether the scanning electron microscope equipment 200 will deteriorate in the future will be described next below.

First, the trend component diagnosis unit 121 generates a trend prediction model (Step S411). The trend prediction model is a model predicting a future temporal development of the trend component included in the time series data. For example, in the polygonal line regression model usage tables 601 to 604 (refer to FIG. 6) generated in step S404 described above, the “intercept” and the “slope” in the third period 509 closest to the current time point can be adopted as the trend prediction model.

Next, the trend component diagnosis unit 121 predicts the future trend of the time series data based on the trend prediction model (step S412). In this example, it is assumed that the setting of the scanning electron microscope equipment 200 is not changed until arbitrary prediction time designated by the user. Under this assumption, the trend component diagnosis unit 121 predicts the future values of the time series data by extending the trend component from the current time to the future by using the “intercept” and the “slope”.

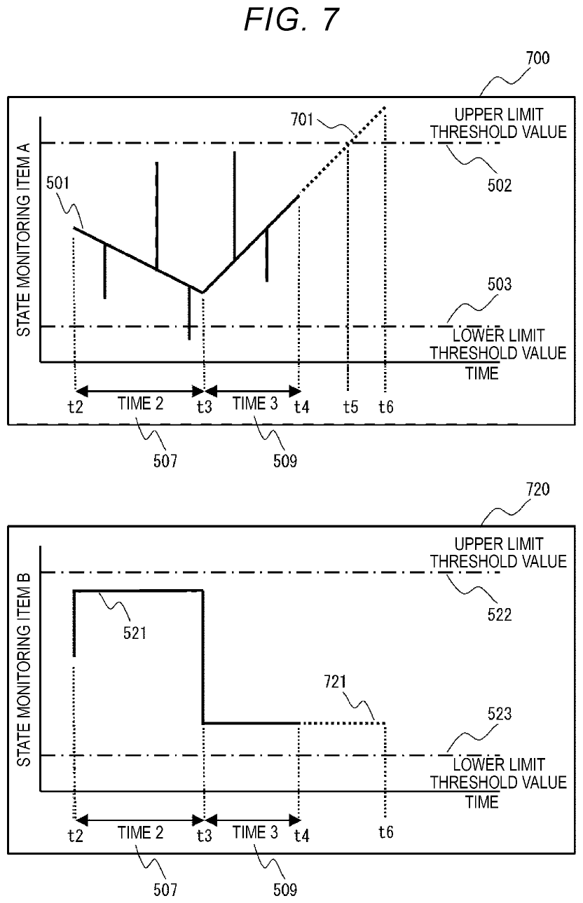

FIG. 7 is a diagram illustrating examples of a graph 700 of the time series data 501 of the monitoring item A and a graph 720 of the time series data 521 of the monitoring item B in which the trend component is extended in this manner.

In this example, it is assumed that the user designates a prediction time point t6. In this case, the trend component diagnosis unit 121 extends the trend component in the third period 509 closest to the current time point to the prediction time point t6 to predict each of the future trend components 701 and 721 of the monitoring item A and the monitoring item B, respectively.

In addition, instead of the user designating the prediction time point t6, the trend component diagnosis unit 121 inputs the arbitrary future time point to the regression model defined by the “intercept” and the “slope” so that the future predicted value of the trend component can be calculated.

In the example of FIG. 7, a time point t5 is a reaching time point when the predicted value of the trend component 701 of the monitoring item A reaches the upper limit threshold value 502. For this reason, at the time point t5, it can be predicted that the deterioration of the scanning electron microscope equipment 200 has progressed to the extent that the maintenance work is required. Then, a difference (t5−t4) between the time point t5 and the time point t4 is a suspension period until the predicted value of the trend component 701 of the monitoring item A reaches the upper limit threshold value 502 when the end time point (t4) of the designated period is used as the reference.

The process refers to FIG. 4 again. Next, the deterioration prediction unit 120 calculates the future deterioration index based on the future trend component predicted in step S412 (step S413). As the deterioration index, there is a numerical value indicating whether the trend component will exceed the normal range defined by the upper limit threshold value 502 and the lower limit threshold value 503 in the future. Further, when it is predicted that the trend component will exceed the normal range in the future, the deterioration prediction unit 120 also calculates the reaching time point and the suspension period described above.

It is noted that the deterioration prediction unit 120 may add or subtract a risk value that is estimated to occur in the future as the fluctuation component to or from the trend component predicted in step S412 and may calculate the deterioration index based on the trend component after the addition or subtraction. As the risk values, there is, for example, an impulse component, a pulsation component, and a random component that occurred in the designated period that is a past period. The maximum value, the minimum value, the average value, and the RMS value of these components in the designated period may be used as the risk value.

Next, the deterioration prediction unit 120 determines whether the scanning electron microscope equipment 200 will deteriorate in the future based on the deterioration index calculated in step S413 (step S414). For example, in the deterioration prediction unit 120, the scanning electron microscope equipment 200 will deteriorate in the future when the trend component exceeds the normal range defined by the upper limit threshold value 502 and the lower limit threshold value 503 as described above in the future, and if not, it is determined that the scanning electron microscope equipment 200 will not deteriorate in the future. Further, the deterioration prediction unit 120 stores the determination result and the deterioration index calculated in step S413 in the storage device 102. It is noted that, when it is determined that the scanning electron microscope equipment 200 will deteriorate in the future, the deterioration prediction unit 120 also stores the reaching time point and the suspension period described above in the storage device 102.

Herein, when it is determined that the scanning electron microscope equipment 200 will not deteriorate in the future (NO in step S414), the process ends.

On the other hand, when it is determined that the scanning electron microscope equipment 200 will deteriorate in the future (YES in step S414), the process proceeds to step S415. In step S415, the deterioration prediction unit 120 instructs the display device 108 to display the diagnosis result.

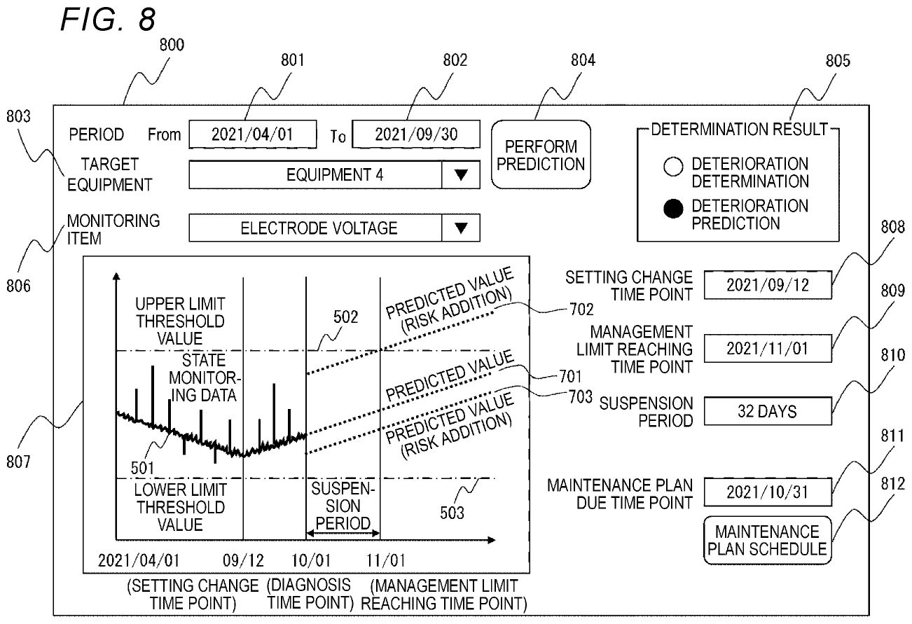

FIG. 8 is a schematic diagram illustrating the screen display example of the display device 108. As illustrated in FIG. 8, a deterioration prediction screen 800 is displayed on the display device 108.

The deterioration prediction screen 800 includes a start time point 801 and an end time point 802 of the designated period. The start time point 801 corresponds to the time point t1 in FIG. 5, and the end time point 802 corresponds to the time point t4 in FIG. 5. It is noted that the end time point 802 is generally a day when the flowchart in FIG. 4 is executed.

Furthermore, the deterioration prediction screen 800 also includes an equipment pull down list 803, a deterioration prediction execution button 804, and a monitoring item pull down list 806.

The equipment pull down list 803 is a list for the user to select the equipment number of the semiconductor manufacturing equipment and the semiconductor inspection equipment. The monitoring item pull down list 806 is a list for the user to select the monitoring item of the equipment.

When the user sets each of the start time point 801, the end time point 802, the equipment pull down list 803, and the monitoring item pull down list 806, and the user presses the deterioration prediction execution button 804, the deterioration prediction device 100 executes the flowchart of FIG. 4. It is noted that, instead of selecting the equipment from the equipment pull down list 803, the flowchart of FIG. 4 may be executed in a batch process for all equipment registered in advance.

In addition, the deterioration prediction screen 800 also includes a determination result display box 805. When the deterioration prediction device 100 determines in step S409 in FIG. 4 that the scanning electron microscope equipment 200 deteriorates within the designated period, the display device 108 marks and displays the “deterioration determination” in the determination result display box 805. In addition, when the deterioration prediction device 100 determines in step S414 in FIG. 4 that the scanning electron microscope equipment 200 will deteriorate in the future (for example, within one year), the display device 108 marks and displays the “deterioration prediction” in the determination result display box 805.

The deterioration prediction screen 800 further includes a deterioration prediction plot area 807. The deterioration prediction plot area 807 is an area displaying the history plot 501 and the future prediction plots 701 to 703 within the designated period of the monitoring item selected from the monitoring item pull down list 806.

The history plot 501 corresponds to the time series data 501 in FIG. 7 and is a plot illustrating the history of the time series data of the monitoring item for the designated period. In addition, the prediction plot 701 corresponds to the future trend component 701 in FIG. 7 and is a plot illustrating the future predicted value of the trend component of the time series data.

Prediction plots 702 and 703 are plots obtained by adding or subtracting the risk value expected to occur in the future from the prediction plot 701. Herein, the prediction plot 702 is obtained by adding the maximum impulse component among the positive impulse components generated in the designated period as the risk value to the prediction plot 701. In addition, the prediction plot 703 is obtained by subtracting the impulse component having the maximum absolute value among the negative impulse components generated in the designated period as the risk value from the prediction plot 701. It is noted that the risk value is not limited to the maximum value of the impulse component. For example, any one of the maximum value, the minimum value, the average value, and the RMS value of any one of the impulse component, the pulsation component, and the random component generated in the designated period may be used as the risk value.

In addition, a “setting change time point”, a “diagnosis time point”, and a “management limit reaching time point” are illustrated in the deterioration prediction plot area 807.

The “setting change time point” is the most recent time point when the setting of the scanning electron microscope equipment 200 is estimated to be changed, and corresponds to time point t3 in FIG. 5. A plurality of periods with the “setting change time point” set as a boundary are displayed in the deterioration prediction plot area 807. As in this example, when the “setting change time point” is 2021 Sep. 12, the period from 2021 Apr. 1 to 2021 Sep. 12 and the period from 2021 Sep. 12 to 2021 Oct. 1 are examples of such a plurality of periods.

The “diagnosis time point” is the time point when the deterioration prediction device 100 executes the flowchart of FIG. 4, and generally, is the day after the date indicated by the end time point 802.

The “control limit reaching time point” is the earliest time point when any one of the prediction plots 701 to 703 is expected to exceed the normal range defined by the upper limit threshold value 502 and the lower limit threshold value 503 and corresponds to the time point t5 in FIG. 7.

The deterioration prediction screen 800 displays a setting change time point display box 808 displaying the setting change time point and a control limit reaching time point display box 809 displaying the control limit reaching time point.

Furthermore, a suspension period display box 810, a maintenance plan due time point display box 811, and a maintenance plan schedule button 812 are displayed on the deterioration prediction screen 800.

The suspension period display box 810 is a box for displaying the suspension period, which is a difference between the control limit reaching time point and the diagnosis time point. The maintenance plan due time point display box 811 is a box for displaying the maintenance plan due time point when the maintenance work for the scanning electron microscope equipment 200 is to be performed. The maintenance plan due time point is registered in, for example, the maintenance plan system (not illustrated).

The maintenance plan schedule button 812 is a button for activating the maintenance plan system (not illustrated). For example, when the control limit reaching time point reaches earlier than the maintenance plan due time point, the scanning electron microscope equipment 200 will have deteriorated remarkably by the maintenance plan due time point. Therefore, in this case, the user activates the maintenance plan system by pressing the maintenance plan schedule button 812 and re-plans the maintenance plan schedule so that the maintenance plan due time point comes earlier than the control limit reaching time point.

It is noted that, although the user selects the monitoring item from the monitoring item pull down list 806 in this example, the monitoring item used for the determination in step S409 or step S414 in FIG. 4 may be automatically selected. In this case, the history plot 501 and the prediction plots 701 to 703 of the monitoring items used for determination in step S409 or step S414 are displayed in the deterioration prediction plot area 807.

By displaying such a deterioration prediction screen 800, the user can grasp each of the control limit reaching time point, the suspension period, and the maintenance plan due time point.

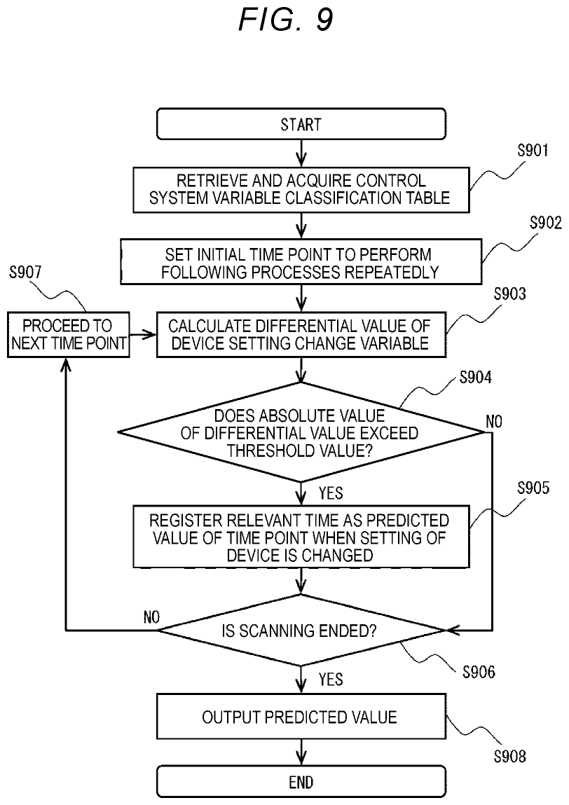

By doing so, the basic processes of the deterioration prediction method according to this embodiment are completed. Next, detailed processing contents of the estimation process in step S402 of FIG. 4 will be described. FIG. 9 is a diagram illustrating an example of a flowchart of the estimation process in step S402 of FIG. 4.

First, the estimation unit 111 retrieves and acquires the control system variable classification table (not illustrated) of the monitoring items from the storage device 102 (step S901).

The control system variable classification table is a table in which each of the plurality of the monitoring items is classified into one of a controlled target variable, a control manipulation variable, an equipment setting change variable, and an observation variable and is generated in advance by the user to be stored in the storage device 102.

The controlled target variable is a variable to be controlled. In this embodiment, the “electron beam current” is a controlled target variable.

The control manipulation variable is a variable for maintaining and stabilizing the controlled target variable at a target value and is a variable that is likely to be arbitrarily fluctuated due to automatic feedback control. In this embodiment, the “filament current” or the “electrode voltage” for maintaining and stabilizing the “electron beam current” at the target current value is a candidate for the control manipulation variable. When there are a plurality of the candidates in this manner, the candidate with good responsiveness and stability among the plurality of candidates may be adopted as the control manipulation variable.

The equipment setting change variable is an item changing the setting of the equipment and is a variable maintained at a constant value unless the variable is changed by adjustment or maintenance. Herein, among the plurality of candidates for the control manipulation variables, the variable not selected as the control manipulation variable is set as the equipment setting change variable. For example, when the “filament current” is a control manipulation variable, the “electrode voltage” is the equipment setting change variable.

The control manipulation variable corresponds to the monitoring item A in FIG. 5, and the equipment setting change variable corresponds to the monitoring item B in FIG. 5. Therefore, when the monitoring item A in FIG. 5 is the “filament current”, the monitoring item B in FIG. 5 is the “electrode voltage”.

The observation variable is the variable that is not classified as any one of the controlled target variable, the control manipulation variable, and the equipment setting change variable. In this embodiment, the “emission current”, the “pressure”, and the “temperature” are observation variables.

Next, the estimation unit 111 specifies the equipment setting change variable from the control system variable classification table, sets an initial time point of the time series data of the equipment setting change variable (step S902) and scans each time point in the time order to repeat the following steps of step S903 to step S907.

Next, the estimation unit 111 calculates the differential value of the equipment setting change variable by dividing the difference between the two values of the equipment setting change variable separated by the predetermined time interval by the time interval (step S903).

Subsequently, the estimation unit 111 determines whether the absolute value of the differential value has exceeded the threshold value (step S904). When the equipment setting change variable is changed due to the maintenance work or the like, the value of the time series data changes abruptly at the time point of change (inflection point). The threshold value for the differential value is a value determined in advance by the user to specify the inflection point on the time series data. When the absolute value of the differential value exceeds the threshold value, it can be estimated that, due to the maintenance work, the equipment setting change variable has been changed.

Herein, when it is determined that the absolute value of the differential value has exceeded the threshold value (YES in step S904), the process proceeds to step S905. In step S905, the estimation unit 111 registers the time point (inflection point) at which the absolute value of the differential value exceeds the threshold value as the estimated value at the time point when the setting of the scanning electron microscope equipment 200 is changed in the storage device 102.

It is noted that the time interval used to calculate the differential value and the threshold value define the sensitivity of the estimation at the time point when the setting is changed. For example, when the time interval is lengthened, it is possible to be prevented from erroneously estimating the time point when the fluctuation occurs at a short interval as the time point when the setting is changed. In addition, by increasing the threshold value, it is possible to be prevented from erroneously estimating the time point when the small fluctuation occurs as the time point when the setting is changed.

Next, the estimation unit 111 determines whether the scanning for all times of the time series data is completed (step S906). It is noted that, when it is determined in step S904 that the absolute value of the differential value does not exceed the threshold value (NO in step S904), step S906 is also executed.

When it is determined that the scanning is not completed (NO in step S906), the process proceeds to step S907, and step S903 is executed for the next time point.

On the other hand, when it is determined that the scanning is completed (YES in step S906), the process proceeds to step S908. In step S908, the estimation unit 111 outputs the estimated value registered in step S905.

With the above, the basic process of the estimation process in step S402 of FIG. 4 is completed.

According to this embodiment described above, the timing point when the setting of the semiconductor manufacturing equipment or the semiconductor inspection equipment is changed is estimated, the time series data is divided into the plurality of periods with the time point as a boundary, and the trend component for each period is discriminated from the time series data. For this reason, even when the tendency of the trend component of the time series data changes, the deterioration of the equipment can be predicted with high accuracy based on the trend component.

Furthermore, the trend component diagnosis unit 121 constructs the trend prediction model (step S411) and predicts the future trend by extending the trend component (step S412). Accordingly, it is possible to determine not only whether the equipment has deteriorated in its current state (step S409), but also whether the equipment will deteriorate in the future (step S414).

In addition, the risk values such as the impulse component, the pulsation component, and the random component that occurred in the past are added to or subtracted from the trend component predicted in step S412, and the deterioration index is calculated based on the trend component. For this reason, the reaching time point when the trend component exceeds the normal range defined by the upper limit threshold value 502 and the lower limit threshold value 503 can be predicted with high accuracy while taking into account the risks derived from the past results.

Moreover, in step S903, the estimation unit 111 calculates the differential value of the time series data of the equipment setting change variable specified from the control system variable classification table. For this reason, in step S905, the estimation unit 111 can estimate the time point when the absolute value of the differential value exceeds the threshold value as the time point when the setting of the equipment is changed. Furthermore, the sensitivity of estimation can be adjusted by adjusting the threshold value and the time interval used to calculate the differential value.

Further, when the user presses the maintenance plan schedule button 812 on the deterioration prediction screen 800, the maintenance plan system can be activated. Accordingly, it is possible for the user to re-plan the maintenance plan so that the operation of the equipment does not stop due to the deterioration of the equipment.

In addition, a maintenance part procurement system (not illustrated) may be activated from the deterioration prediction screen 800. Accordingly, the user can procure the maintenance parts by the maintenance plan due time point with reference to future deterioration prediction of the equipment.

This embodiment may be performed not only by the equipment user who manufactures or inspects the semiconductor devices or may be performed but also by an equipment maker of the semiconductor manufacturing equipment or the semiconductor inspection equipment as the maintenance service. In a case of being performed by the equipment maker, a service that proposes the equipment user to perform maintenance based on the prediction of the deterioration or a service that procures and prepares maintenance parts in advance of the occurrence of the deterioration and supplies the maintenance parts to the equipment user without delay can be implemented.

### Second Embodiment

In the first embodiment, the estimation unit 111 acquires the control system variable classification table (step S901) and the estimation unit 111 estimates the time point of changing the setting of the equipment based on the differential value of the equipment setting change variable included in the control system variable classification table (step S905). This method is useful when the user has a knowledge of classifying the plurality of the monitoring items and generating the control system variable classification table. This embodiment to be described below is the useful method in a case where there is no such knowledge, in a case where there is no equipment setting change variable in the first place, or in a case where only the replacement of maintenance parts is not directly reflected in a particular monitoring item.

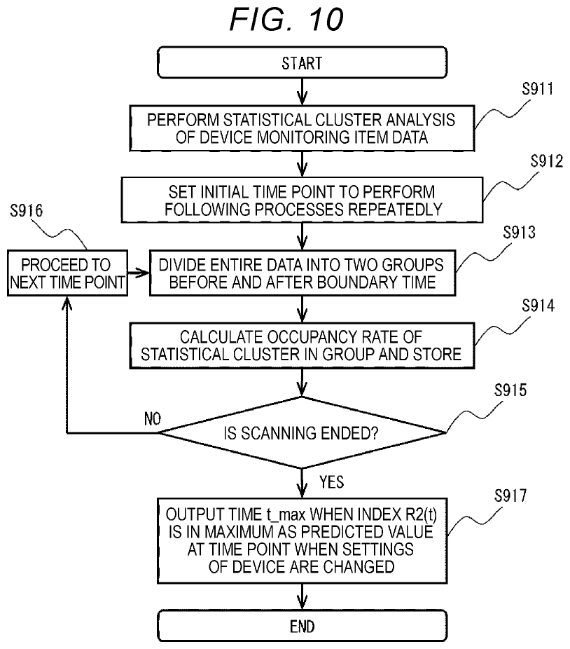

FIG. 10 is a diagram illustrating an example of a flowchart in this embodiment of the estimation process in step S402 of FIG. 4. This flowchart is implemented by employing the time series cluster analysis as follows.

First, the estimation unit 111 applies a statistical cluster analysis to the time series data of the monitoring items (step S911). The time series data is configured with the plurality of pieces of data in which the time data and the values of the monitoring items are associated with each other, and each of the plurality of pieces of data is denoted by the statistical cluster number in this process. Methods of the statistical cluster analysis include, for example, a K-means method. Techniques other than this may be adopted as techniques for the statistical cluster analysis.

The monitoring items that are targets of the statistical cluster analysis in this step are not particularly limited. However, since the control manipulation variable is a variable that allows the controlled target variable such as the “electron beam current” to be constant, it is likely to fluctuate under the influence of the deterioration of the equipment. For this reason, it is preferable to apply the statistical cluster analysis to the control manipulation variables so that the results of the cluster analysis clearly illustrate the deterioration of the equipment.

When the statistical cluster analysis is applied to the time series data in this manner, each data can be classified into the predetermined number of clusters based on a distance between the respective data without considering the time of each data. However, the boundaries of clusters are appropriate division values within a data value range, and the time boundaries of the respective clusters cannot be obtained by only the statistical cluster analysis. Therefore, the time series cluster analysis is performed after step S912 as follows.

The estimation unit 111 sets an initial time point of the time series data of the monitoring item (step S912) and repeats the following steps S913 to S916 by scanning each time point of the time series data of the monitoring item in order of time. In this manner, the boundary point on the time series data that is to approximate the boundary times of the plurality of statistical clusters obtained in step S911 with the highest accuracy is searched. For simplicity, it is assumed that the number of statistical clusters obtained in step S911 is two.

First, the estimation unit 111 divides all the data on the time series data into two groups before and after the time point with the certain boundary time on the time series data as the boundary (step S913).

Next, the estimation unit 111 calculates the occupancy rate of the statistical cluster for each of the two groups based on the identifier assigned to each data and stores the result in the storage device 102 (step S914).

For example, among the two groups, the array storing data belonging to the group of which time point is the boundary time or less is denoted by X1, and the array storing data belonging to the group of which time point is larger than the boundary time is denoted by X2.

The identifiers of the two statistical clusters obtained in step S911 are denoted by C1 and C2. The number of data belonging to C1 is denoted by N1, and the number of data belonging to C2 is denoted by N2. The function listing the number of elements belonging to the cluster C among the elements of the array X is written as follows.

N=count(X, C)

In this case, a number Nij (1≤i, j≤2) of elements belonging to a statistical cluster Cj among the elements belonging to an array Xi can be written as follows.

N11=count(X1, C1)

N12=count(X1, C2)

N21=count(X2, C1)

N22=count(X2, C2)

In addition, the occupancy rate is defined as follows.

R11=N11/N1

R12=N12/N2

R21=N21/N1

R22=N22/N2

In step S914, the estimation unit 111 calculates these occupancy rates R11, R12, R21, and R22.

Next, the estimation unit 111 determines whether the scanning for all times of the time series data is completed (step S915).

Herein, when it is determined that the scanning is not completed (NO in step S915), the process proceeds to step S916, and step S913 is executed for the next time point.

On the other hand, when it is determined that the scanning is completed (YES in step S915), the process proceeds to step S917. In step S917, the estimation unit 111 outputs the time when the index calculated from the occupancy rate reaches the maximum thereof as the estimated value at the time point when the setting of the equipment is changed (step S917).

For example, when N11≥N21 with a certain time as the time boundary, the array X1 mainly belongs to the statistical cluster C1 and the array X2 mainly belongs to the statistical cluster C2, and the estimation unit 111 calculates the product R2(t)=R11×R22 of the occupancy rates R11 and R22 as the index.

On the contrary, when N11<N21 with a certain time t as the time boundary, the array X1 mainly belongs to the statistical cluster C2 and the array data X2 mainly belongs to the statistical cluster C1, and the estimation unit 111 calculates the product R2(t)=R12×R21 of the occupancy rates R12 and R21 as the index.

The index R2(t) becomes the function of the time point t. The estimation unit 111 specifies the time t_max when the index R2(t) is in maximum as the boundary time that becomes a boundary between the clusters C1 and C2 and outputs the boundary time as the estimated value of the time point when the setting of the equipment is changed.

It is noted that, in this example, the case where the number of statistical clusters is two has been described as the example, but even in a case where the number of statistical clusters is an arbitrary number, the estimated value of the time when the setting of the equipment is changed can be similarly obtained. Alternatively, the estimated value in step S917 may be calculated by fixing the number of statistical clusters to two, and the process of FIG. 10 may be recursively applied to two pieces of the time series data divided by the estimated value as a boundary value.

With the above, the basic process of the estimation process in step S402 according to this embodiment is completed.

In this embodiment described above, the monitoring item targeted for the cluster analysis is not limited to the equipment setting change variables, and an arbitrary monitoring item can be targeted for the cluster analysis. For this reason, even when the user does not have a knowledge for classifying a plurality of the monitoring items and generating the control system variable classification table, or when there are no equipment setting change variables, or when only the replacement of maintenance parts is not directly reflected in a particular monitoring item, the time point when the setting of the equipment is changed can be estimated.

In addition, in this embodiment, it is possible to detect the boundary time that can only be obtained when the entire time series data are to be viewed from the perspective of the distance between each data point other than the changing point of an equipment state that clearly appears in the time series data as the time point of abrupt change of the equipment setting change variable. For this reason, in this embodiment, unknown changes appearing in the time series data can be captured.

It is noted that the deterioration prediction device 100 may instruct the alarm device 109 to issue the alarm when detecting the boundary time indicating such an unknown change. Accordingly, it is possible for the user to take early countermeasures against unknown abnormalities in the equipment.

In addition, according to FIG. 9 of the first embodiment, the time when the setting of the equipment is changed is estimated, the time series data is divided in a period bordering on that time, and this embodiment may be applied to the time series data for each period. Accordingly, it is possible to more accurately estimate the time when the setting of the equipment is changed.

The effects described herein are only examples and are not limited, and other effects may be provided.

The present invention is not limited to the above-described embodiments, and includes various modifications. For example, each of the above-described embodiments has been described in detail in order to explain the present invention in the easy-to-understand manner, and the present invention is not necessarily limited to those having all the described components. In addition, a portion of the configuration of one embodiment can be replaced with the configuration of another embodiment, and the configuration of another embodiment can be added to the configuration of one embodiment. Moreover, it is possible to add, delete, or replace a portion of the configuration of each embodiment with another configuration.

Further, each of the configurations, the functions, the processing units, the processing means, and the like described above may be realized by hardware, for example, by designing the configuration and the like in an integrated circuit. In addition, each of the configurations, the functions, and the like described above may be realized by software by the processor interpreting and executing the program for realizing the respective functions. Information of the programs, the determination tables, the files, and the like that realize each function can be stored in a storage device such as a memory, an HDD, and an SSD or a recording medium such as an integrated circuit (IC) card, a secure digital (SD) card, and a DVD. In addition, the control lines and the information lines indicate those considered necessary for the description, and not all control lines and information lines are necessarily indicated on a product. In practice, it may be considered that almost all configurations are interconnected.

What is claimed is:

1. A deterioration prediction system for semiconductor manufacturing equipment or semiconductor inspection equipment, comprising:
an input device receiving, as an input, time series data indicating a state of the equipment;
a deterioration prediction device having an estimation unit discriminating fluctuation in the time series data into fluctuation caused by changing setting of the equipment and fluctuation caused by deterioration of the equipment and estimating a time point when the setting is changed, a division unit dividing the time series data into the plurality of periods bounded by the time points, a discrimination unit discriminating at least a trend component from the fluctuation in the time series data in the period, and a prediction unit predicting the deterioration of the equipment based on at least the trend component, and
an output device outputting a result of the prediction.

2. The deterioration prediction system for semiconductor manufacturing equipment or semiconductor inspection equipment according to claim 1, wherein the estimation unit estimates an inflection point of the time series data of the equipment setting change variable, which is an item for changing the setting of the equipment, as the setting change time point.

3. The deterioration prediction system for semiconductor manufacturing equipment or semiconductor inspection equipment according to claim 1, wherein the estimation unit classifies the time series data into statistical clusters by the statistical cluster analysis and specifies the boundary time that is the boundary of the plurality of statistical clusters by a time series cluster analysis and estimates the specified boundary time as the setting change time point.

4. The deterioration prediction system for a semiconductor manufacturing equipment or a semiconductor inspection equipment according to claim 1, wherein the prediction unit generates a regression model of the trend component for each of the periods with the setting change time point as the boundary and inputs the arbitrary time in the future of the regression model to calculate a predicted value of the trend component of the time series data, determines whether the predicted value is within or outside a range between predetermined threshold values, and predicts the deterioration of the equipment in the future based on a result of the determination.

5. The deterioration prediction system for a semiconductor manufacturing equipment or a semiconductor inspection equipment according to claim 1, wherein the prediction unit performs the prediction by adding or subtracting a fluctuation component estimated from at least one of the impulse component, the pulsation component, and the random component that occurred in the past to or from the trend component.

6. The deterioration prediction system for a semiconductor manufacturing equipment or a semiconductor inspection equipment according to claim 1, wherein the output device outputs a history plot illustrating a history of the time series data, a prediction plot illustrating the predicted value of the trend component of the time series data, the setting change time point, the period, a reaching time point when the predicted value reaches the threshold value, and a suspension period until the reaching time point, or a maintenance plan due time point of the equipment.

7. The deterioration prediction system for semiconductor manufacturing equipment or semiconductor inspection equipment according to claim 1, wherein the output device displays a screen with a button for activating the maintenance plan system of the equipment.

8. The deterioration prediction system for semiconductor manufacturing equipment or semiconductor inspection equipment according to claim 1,
wherein the equipment is a charged particle beam equipment including the filament emitting the particle beam and the electrode accelerating the particle beam, and
wherein the time series data is time series data of any of the current values of the particle beam, the current value of the current supplied to the filament, or the voltage value of the voltage applied to the electrode.

9. A deterioration prediction method for semiconductor manufacturing equipment or semiconductor inspection equipment, causing a computer to:
determine fluctuation in time series data indicating a state of equipment into fluctuation caused by changing setting of the equipment and fluctuation caused by deterioration of the equipment and estimate a time point when the setting is changed;
divide the time series data into the plurality of periods bounded by the time points;
discriminate at least a trend component from the fluctuation of the time series data in the period; and
predict the deterioration of the equipment based on at least the trend component.
